(19) United States
(12) Patent Application Publication
(10) Pub. No.: US 2026/0214797 A1
(43) Pub. Date: Jul. 23, 2026

(54) POWER PIN ASSEMBLY STRUCTURE OF ELECTRONIC DEVICE AND MANUFACTURING PROCESS FOR SUBSTRATE THEREOF

(71) Applicant: MetaPWR Electronics Co., Ltd., Shanghai (CN)

(72) Inventors: Liuzhu Li, Shanghai (CN); Qingdong CHEN, Shanghai (CN); Shouyu HONG, Shanghai (CN)

(73) Assignee: MetaPWR Electronics Co., Ltd., Shanghai (CN)

(21) Appl. No.: 19/454,400

(22) Filed: Jan. 21, 2026

(30) Foreign Application Priority Data
Jan. 21, 2025 (CN) 202510090666.9

(51) Int. Cl. H05K 1/11; H05K 3/00; H05K 3/3465; H05K 3/42

(52) U.S. Cl. CPC H05K 1/113; H05K 3/0047; H05K 3/3465; H05K 3/42; H05K 2201/09572; H05K 2201/09845; H05K 2201/09854; H05K 2201/10303

(57) ABSTRACT

The present application discloses a power pin assembly structure of an electronic device, the plated through hole comprises a first through-hole portion and a second through-hole portion, a cross-sectional area of the second through-hole portion is smaller than a cross-sectional area of the first through-hole portion, and the first through-hole portion and the second through-hole portion are stacked to form a stepped hole; by welding between the sidewall of the first implantation portion and the sidewall of the first through-hole portion, and welding between the support surface and the welding portion, the connection reliability between the power pin and the substrate is enhanced.

### CROSS-REFERENCE TO RELATED APPLICATIONS

This application claims the priority benefit of Chinese patent application 202510090666.9 filed on January 21, 2025. The entirety of the above-mentioned patent application is hereby incorporated by reference herein and made a part of this specification.

### BACKGROUND

In recent years, with the increasing requirements of various types of artificial intelligence, data processing, etc., the computing capabilities of various board cards are continuously increased, and the power consumption of a computing chip is also increased year by year. Therefore, the number of layers of the mainboard of the power module is also increased, and the thickness of the main board is also increased accordingly. For example, the mainboard wiring layer is greater than or equal to 12 layers, and the thickness is greater than or equal to 2 mm.

Most of the power pins are led out by means of welding a copper column in a through hole. Since a surface mounted technology (SMT) process is used in the production process of the power module, due to the relatively limited amount of the solder paste in the hole, how to ensure a good weld filling of the copper column in the through-hole of the main board is an urgent problem to be solved in the production of the power module.

### TECHNICAL FIELD

The present application relates to the technical field of electronic devices, and in particular to a power pin assembly structure of an electronic device and a manufacturing process for a substrate thereof.

### SUMMARY

In view of the above, one of the objectives of the application is to provide a power pin assembly structure of an electronic device, comprising a substrate and a power pin;

the substrate comprises a plated through hole, an upper surface and a lower surface opposite to each other; the plated through hole penetrates the upper surface and the lower surface of the substrate; the plated through hole comprises a first through-hole portion, a second through-hole portion, a welding portion and a metallization layer; a cross-sectional area of the second through-hole portion is smaller than a cross-sectional area of the first through-hole portion, and the first through-hole portion and the second through-hole portion are stacked to form a stepped hole; the welding portion is disposed on the lower surface of the substrate; the metallization layer is disposed on a sidewall of the first through-hole portion and a region extending from the sidewall of the first through-hole portion towards the second through-hole portion;

the power pin comprises a first implantation portion, a support surface, and a support portion; the support surface is connected to the first implantation portion and the support portion; a cross-sectional area of the first implantation portion is smaller than a cross-sectional area of the support portion; the first through-hole portion is used for accommodating the first implantation portion of the power pin, and a sidewall of the first implantation portion and the sidewall of the first through-hole portion are fixed and electrically connected by means of solder; and the support surface and the welding portion are fixed and electrically connected by means of solder.

Preferably, a thickness of the substrate is greater than 2 mm.

Preferably, the metallization layer is further disposed on a sidewall of the second through-hole portion and a peripheral region of the second through-hole portion on the upper surface of the substrate.

Preferably, the power pin further comprises a second implantation portion, the first implantation portion and the second implantation portion are respectively disposed at two opposite ends of the support portion; the second implantation portion and the other substrate are fixed and electrically connected.

Preferably, the power pin further comprises a third implantation portion, and a cross-sectional area of the third implantation portion is smaller than a cross-sectional area of the first implantation portion; the third implantation portion and the first implantation portion are connected to form a stepped shape, and the third implantation portion is disposed within the second through-hole portion.

Preferably, the first implantation portion and the first through-hole portion are cylindrical.

Preferably, a height of the first implantation portion is less than 75% of a thickness of the substrate.

Preferably, a height of the first implantation portion plus a width of the support surface is greater than 75% of a thickness of the substrate.

The substrate manufacturing process for a power pin assembly structure, comprising the following steps: firstly, forming the first through-hole portion by using a depth-controlled drilling, and then performing a metallization process to form the metallization layer and/or the welding portion; and finally, continuing drilling in a region of the first through-hole portion to form the second through-hole portion.

The substrate manufacturing process for a power pin assembly structure, comprising the following steps: firstly, forming the first through-hole portion by using a depth-controlled drilling, then continuing drilling in a region of the first through-hole portion to form the second through-hole portion, and finally performing a metallization process to form the metallization layer and/or the welding portion.

Compared with the prior art, the application has the following beneficial effects:

(1) By welding between the sidewall of the first implantation portion and the sidewall of the first through-hole portion, and welding between the support surface and the welding portion, the connection reliability between the power pin and the substrate is enhanced.

(2) By means of the arrangement of the second through-hole portion, the ineffective loss of the amount of solder paste is avoided, and an exhaust channel is provided for air in the first through-hole portion, thereby the effective filling rate and uniformity of the solder are further enhanced.

### BRIEF DESCRIPTION OF THE DRAWINGS

FIG. 1A and FIG. 1B are a power pin assembly structure of an electronic device.

FIG. 2A is a side cross-sectional view of a plated through hole.

FIG. 2B is a side cross-sectional view of the power pin assembled within the plated through hole.

FIG. 3 is a power pin assembly structure of another electronic device.

FIG. 4A is another power pin.

FIG. 4B is a side cross-sectional view of another power pin assembled in a plated through hole.

### DESCRIPTION OF THE EMBODIMENTS

One of the cores of the present application is to provide a power pin assembly structure of an electronic device.

Technical solutions in the embodiments of the present disclosure will be clearly and completely described below with reference to the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

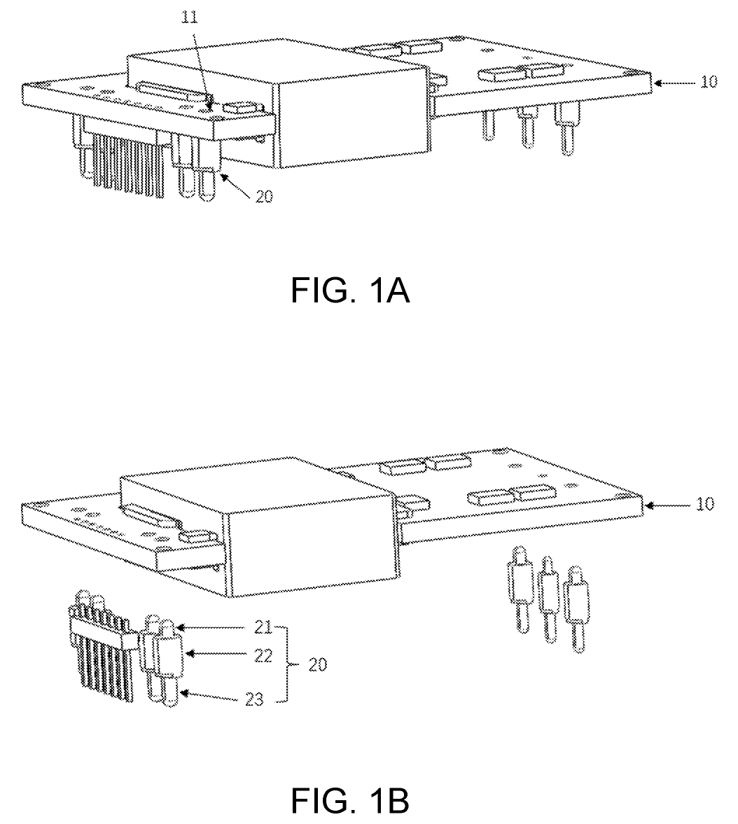

FIG. 1A is an assembly structure of a power pin of an electronic device according to the present disclosure, and FIG. 1B is an exploded view of FIG. 1A. As shown in FIG. 1A and 1B, the electronic device comprises a substrate 10, a power pin 20 and a plated through hole 11. The power pin 20 comprises a first implantation portion 21, a support portion 22 and a second implantation portion 23, and the first implantation portion 21 and the second implantation portion 23 are respectively disposed at two opposite ends of the support portion 22. The substrate 10 comprises an upper surface and a lower surface opposite to each other, the plated through hole 11 is disposed on the substrate 10, and the plated through hole 11 penetrates the upper surface and the lower surface of the substrate 10. The plated through hole 11 is configured to be provided with a first implantation portion 21.

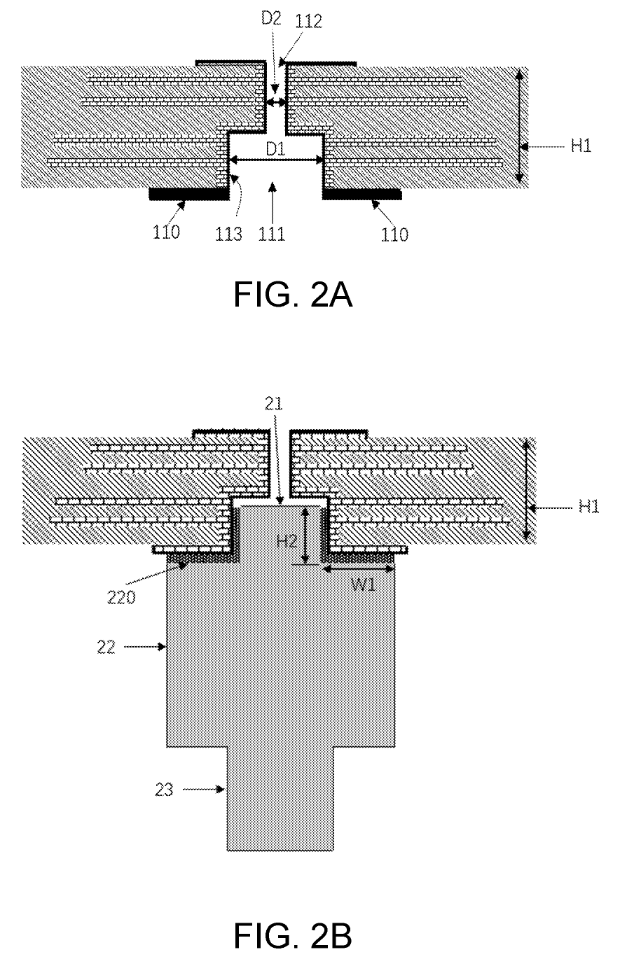

FIG. 2A shows a side cross-sectional view of the plated through hole 11, and FIG. 2B shows a side cross-sectional view of the power pin 20 assembled within the plated through hole 11. The plated through hole 11 comprises a welding portion 110, a first through-hole portion 111, a second through-hole portion 112, and a metallization layer 113; the welding portion 110 is disposed on the lower surface of the substrate 10 and is disposed around the first through-hole portion 111; the first through-hole portion 111 and the second through-hole portion 112 are stacked to form a stepped hole, and the stepped hole penetrates the upper surface and the lower surface of the substrate 10; the diameter D1 of the first through-hole portion is greater than the diameter D2 of the second through-hole portion; the metallization layer 113 is provided on a sidewall of the first through-hole portion 111, a sidewall of the second through-hole portion 112, and a position extending from the side-wall of the first through-hole portion 111 towards the second through-hole portion 112. The thickness of the substrate 10 is H1.

As shown in FIG. 2B, a height of the first implantation portion 21 is H2, and the height H2 is less than or equal to the depth of the first through-hole portion 111. A sidewall of the first implantation portion 21 of the power pin 20 and the sidewall of the first through-hole portion 111 are fixed and electrically connected by means of solder; the power pin 20 further comprises a support surface 220, the support surface 220 is provided between the sidewall of the first implantation portion 21 and the sidewall of the support portion 22, and the sidewall of the first implantation portion 21 and a sidewall of the support portion 22 are connected; and the support surface 220 and the welding portion 110 are fixed and electrically connected by means of solder welding. Preferably, the implantation height H2 is less than 75% of the substrate thickness H1, and/or the height H2 of the implantation portion plus a width W1 of the support surface 220 is greater than 75% of the main board thickness H1. The support surface 220 provides additional welding strength between the power pin and the substrate, thereby the reliability of the welding is effectively ensured. On the other hand, when the solder between the sidewall of the first implantation portion 21 and the sidewall of the first through-hole portion 111 is melted, air can be discharged by means of the second through-hole portion 112, so that no bubbles exist in the solder, and the effective filling rate of the solder is enhanced; moreover, the molten solder rarely spreads toward the second through-hole portion 112, thereby avoiding the loss of the solder paste; and therefore, on the premise of ensuring the limited amount of the solder, the effective welding in the height H2 of the implantation portion is ensured. In addition, because the diameter of the second through-hole portion is smaller than the diameter of the first through-hole portion, the cross section of the second through-hole portion 112 on the upper surface of the substrate 10 is also small, and the influence on the device arrangement and the number of devices on the upper surface of the substrate 10 is also small.

The substrate processing process disclosed in FIGS. 2A and 2B is as follows: firstly, forming the first through-hole portion 111 by using a depth-controlled drilling, and then continuing drilling in a region of the first through-hole portion 111 to form the second through-hole portion 112, and finally performing a metallization process to form the metallization layer 113 and/or the welding portion 110.

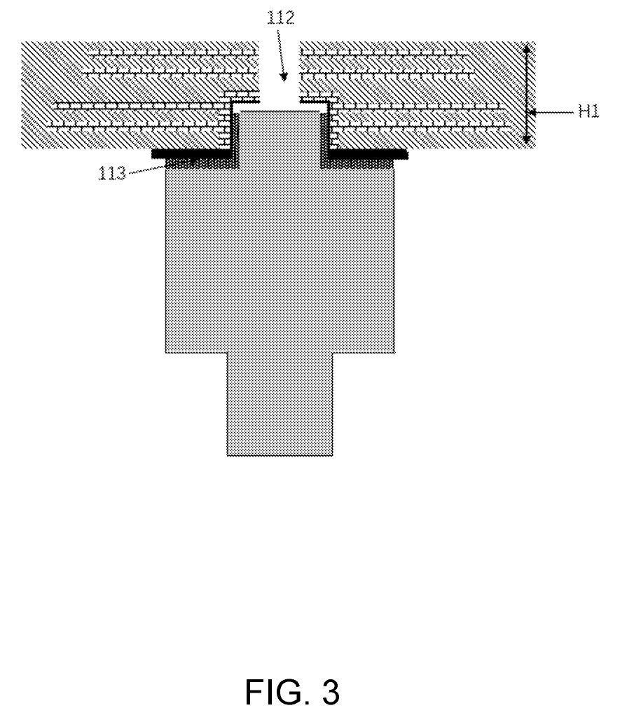

FIG. 3 shows a power pin assembly structure of another electronic device, which differs from FIG. 2A in that the metallization layer 113 is provided at the sidewall of the first through-hole portion 111 and a position extending from the sidewall of the first through-hole portion 111 towards the second through-hole portion 112, and the sidewall of the second through-hole portion 112 is not provided with the metallization layer. The through-hole welded substrate structure is disclosed in FIG. 3, and the substrate processing process is as follows: firstly, forming the first through-hole portion 111 by using a depth-controlled drilling, and then performing the metallization process to form the metallization layer 113 and/or the welding portion 110; finally, continuing drilling in a region of the first through-hole portion 111 to form the second through-hole portion 112, wherein the inner-layer metal corresponding to the sidewall of the second through-hole portion 112 can be selected to be exposed to the side-wall according to requirements.

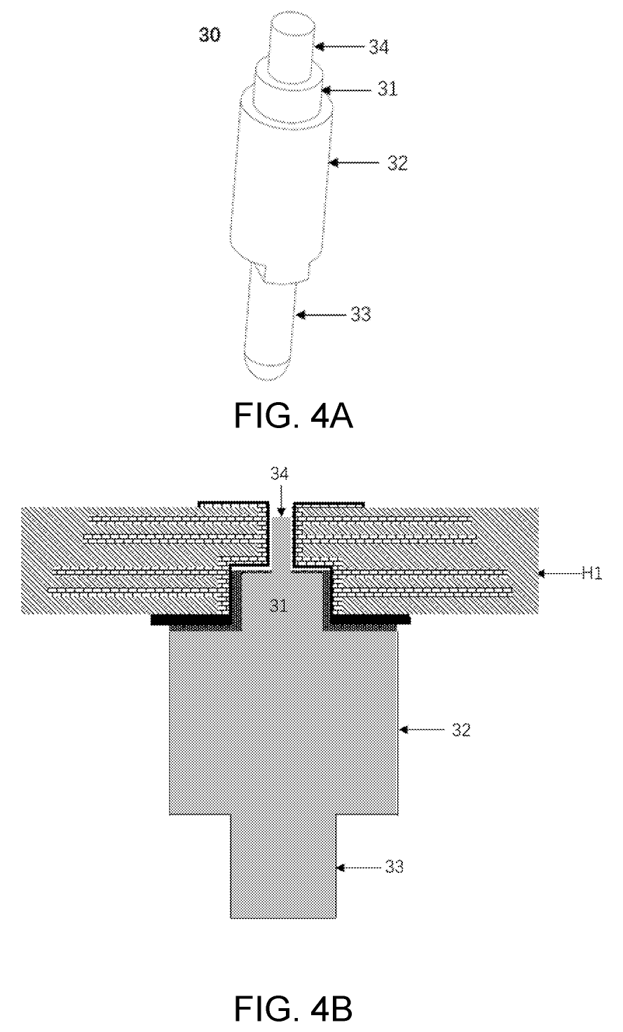

FIG. 4A shows another power pin 30, and FIG. 4B shows a side cross-sectional view of the power pin 30 assembled within the plated through hole 11 shown in FIG. 2A. As shown in FIG. 4A, the power pin 30 comprises a first implantation portion 31, a support portion 32, a second implantation portion 33, and a third implantation portion 34; the third implantation portion 34 is connected to the first implantation portion 31, and the cross-sectional area of the third implantation portion 34 is smaller than the cross-sectional area of the first implantation portion 31, so that the first implantation portion and the third implantation portion form a stepped shape; the third implantation portion 34 is provided within the second through-hole portion 112, so that the overflow of solder can be prevented under the premise of ensuring the exhaust function, and the filling performance of the solder is further improved.

In addition, the second implantation portion 23 of the power pin 20 and the other substrate are fixed and electrically connected, and the other substrate can also use the same substrate structure as described in the above embodiments to achieve the same technical effect. In other embodiments, the power pin may also include only the first implantation portion and the support portion, and the power pin and the metalized plated through hole of the substrate are fixed and electrically connected by using the foregoing embodiments, so that the same technical effect can be obtained. In addition, the shape of the first through-hole portion and the second through-hole portion are not limited to a cylindrical shape, and the cross-sectional area of the first through-hole portion and the second through-hole portion may also be square or elliptical, but is preferably circular; however, the shape of the first implantation portion, the second implantation portion, and the support portion is not limited to the cylindrical shape, and the cross-sectional area of the first implantation portion, the second implantation portion, and the support portion may also be square or elliptical, but is preferably circular.

The thickness of the substrate according to the above embodiment is greater than or equal to 2 mm. The electronic device according to the above embodiment can also be a part of a power supply module or other electronic devices, and can also satisfy the technical features and benefits disclosed in the present application.

The " equal " or " same " or " equal to " disclosed by the application needs to consider the parameter distribution of engineering, and the error distribution is within +/-30%; and the included angle between the two line segments or the two straight lines is less than or equal to 45 degrees; the included angle between the two line segments or the two straight lines is within the range of [ 60, 120 ]; and the definition of the phase error phase also needs to consider the parameter distribution of the engineering, and the error distribution of the phase error degree is within +/-30%.

The embodiments in the specification are described in a progressive manner, each embodiment focuses on the difference from other embodiments, and the same similar parts between the embodiments can be referred to each other.

The above description of the disclosed embodiments enables a person skilled in the art to implement or use the present application. Various modifications to these embodiments will be readily apparent to those skilled in the art, and the generic principles defined herein may be implemented in other embodiments without departing from the spirit or scope of the application. Thus, the present application will not be limited to the embodiments shown herein but is to be accorded the widest scope consistent with the principles and novel features disclosed herein.

What is claimed is:

1. A power pin assembly structure of an electronic device, comprising a substrate and a power pin;
the substrate comprises a plated through hole, an upper surface and a lower surface opposite to each other; the plated through hole penetrates the upper surface and the lower surface of the substrate; the plated through hole comprises a first through-hole portion, a second through-hole portion, a welding portion and a metallization layer; a cross-sectional area of the second through-hole portion is smaller than a cross-sectional area of the first through-hole portion, and the first through-hole portion and the second through-hole portion are stacked to form a stepped hole; the welding portion is disposed on the lower surface of the substrate; the metallization layer is disposed on a sidewall of the first through-hole portion and a region extending from the sidewall of the first through-hole portion towards the second through-hole portion;
the power pin comprises a first implantation portion, a support surface, and a support portion; the support surface is connected to the first implantation portion and the support portion; a cross-sectional area of the first implantation portion is smaller than a cross-sectional area of the support portion; the first through-hole portion is used for accommodating the first implantation portion of the power pin, and a sidewall of the first implantation portion and the sidewall of the first through-hole portion are fixed and electrically connected by means of solder; and the support surface and the welding portion are fixed and electrically connected by means of solder.

2. The power pin assembly structure of claim 1, wherein a thickness of the substrate is greater than 2 mm.

3. The power pin assembly structure of claim 2, wherein the metallization layer is further disposed on a sidewall of the second through-hole portion and a peripheral region of the second through-hole portion on the upper surface of the substrate.

4. The power pin assembly structure of claim 1, wherein the power pin further comprises a second implantation portion, the first implantation portion and the second implantation portion are respectively disposed at two opposite ends of the support portion; the second implantation portion and the other substrate are fixed and electrically connected.

5. The power pin assembly structure of claim 1, wherein the power pin further comprises a third implantation portion, and a cross-sectional area of the third implantation portion is smaller than a cross-sectional area of the first implantation portion; the third implantation portion and the first implantation portion are connected to form a stepped shape, and the third implantation portion is disposed within the second through-hole portion.

6. The power pin assembly structure of claim 1, wherein the first implantation portion and the first through-hole portion are cylindrical.

7. The power pin assembly structure of claim 1, wherein a height of the first implantation portion is less than 75% of a thickness of the substrate.

8. The power pin assembly structure of claim 1, wherein a height of the first implantation portion plus a width of the support surface is greater than 75% of a thickness of the substrate.

9. A substrate manufacturing process for the power pin assembly structure of claim 1, wherein the substrate manufacturing process comprises the following steps: firstly, forming the first through-hole portion by using a depth-controlled drilling, and then performing a metallization process to form the metallization layer and/or the welding portion; and finally, continuing drilling in a region of the first through-hole portion to form the second through-hole portion.

10. A substrate manufacturing process for the power pin assembly structure of claim 3, wherein the substrate manufacturing process comprises the following steps: firstly, forming the first through-hole portion by using a depth-controlled drilling, then continuing drilling in a region of the first through-hole portion to form the second through-hole portion, and finally performing a metallization process to form the metallization layer and/or the welding portion.
